(19) United States
(12) Patent Application Publication
(10) Pub. No.: US 2024/0222546 A1
(43) Pub. Date: Jul. 4, 2024

(54) MANUFACTURING METHOD FOR HIGH-VOLTAGE LED CHIP

(71) Applicant: FOCUS LIGHTINGS TECH CO., LTD, Suzhou, Jiangsu (CN)

(72) Inventors: Wenguang HUANG, Suzhou (CN); Xiaoxiong LIN, Suzhou (CN); Zhen ZHANG, Suzhou (CN); Hongfeng WANG, Suzhou (CN); Yufei CAO, Suzhou (CN)

(73) Assignee: FOCUS LIGHTINGS TECH CO., LTD, Suzhou, Jiangsu (CN)

(21) Appl. No.: 17/791,139

(22) PCT Filed: Feb. 16, 2022
(86) PCT No.: PCT/CN2022/076491

§ 371 Date: Jul. 27, 2023

(30) Foreign Application Priority Data
Jan. 18, 2022 (CN) 202210053067.6

(51) Int. Cl. H01L 33/00; H01L 33/06; H01L 33/20; H01L 33/32; H01L 33/42; H01L 33/46

(52) U.S. Cl. CPC H01L 33/007; H01L 33/06; H01L 33/20; H01L 33/32; H01L 33/42; H01L 33/46; H01L 2933/0016; H01L 2933/0025

(57) ABSTRACT

The present application provides a manufacturing method for a high-voltage LED chip. The sapphire substrate PSS in the embodiments of the present application has a double-layer structure with an upper layer and a lower layer, the upper layer being silicon oxide (SiO₂), and the lower layer being sapphire Al₂O₃. Before making the sapphire Al₂O₃ patterned, a layer of silicon oxide (SiO₂) is deposited on the sapphire Al₂O₃, and then the sapphire substrate PSS is made by dry etching, and the substrate is used to fabricate the high-voltage LED chip. After etching and bridging the isolation groove by the inductively coupled plasma ICP, the sapphire substrate PSS is corroded. The silicon oxide (SiO₂) above the sapphire Al₂O₃ is removed. A flat platform is formed at the isolation groove of the high-voltage LED chip, which is convenient to subsequently cover the bridging metal, thereby solving the problems such as bridging metal fractures.

### CROSS-REFERENCE TO RELATED APPLICATION

The present application claims the priority to the Chinese patent application No. 202210053067.6, entitled “Manufacturing Method for High-Voltage Led Chip”, filed with the China National Intellectual Property Administration on Jan. 18, 2022, which is incorporated herein by reference in its entirety.

### FIELD OF THE PRESENT DISCLOSURE

The present application relates to the field of semiconductor device manufacturing, and more particularly to a manufacturing method for a high-voltage LED chip.

### BACKGROUND OF THE PRESENT DISCLOSURE

A light-emitting diode, referred to as LED for short, is a commonly used light-emitting device. The LED has the characteristics of energy-saving, environmental protection, reliable safety, long life, and low power consumption, and can be widely used in various fields, such as indicating, displaying, decorating, backlight, general lighting, etc. Compared with the common LED chips, the high-voltage LED chip has the advantages of low current, high voltage, no need for large-amplitude voltage conversion, small transformation loss, simple driving design, and low heat dissipation requirements, and the high-voltage LED chip can reduce the packaging cost, reduce the number of elements and welding spots, and have high reliability performance. Therefore, the application of the high-voltage LED chip is more and more widespread.

FIG. 1 is a schematic view of a cross-sectional structure of a high-voltage LED chip product in an embodiment. FIG. 2 is a schematic view of a cross-section of an isolation groove of the high-voltage LED chip product in FIG. 1, and the dotted box portion in FIG. 2 is the isolation groove. With reference to FIGS. 1 and 2, the isolation groove of a current high-voltage LED chip usually uses an Inductively Coupled Plasma (ICP) process to etch an epitaxial layer (from the N-type gallium nitride to the P-type gallium nitride in FIG. 2 is the epitaxial layer) from the N-type gallium nitride (N-GaN) to the substrate of the sapphire Al₂O₃. Gases such as boron trichloride (BCl₃) or chlorine (Cl₂) are usually used for etching. The angle of the isolation groove is usually controlled between 20° to 60° to cover the bridging metal.

However, in the above-mentioned method, due to technological and process reasons, the patterned sapphire substrate (PSS) on the sapphire Al₂O₃ cannot be planarized; the shape of the PSS is similar to the shape of a Mongolian yurt, and the head thereof is sharp, which would lead to poor metal bridging coverage at the isolation groove of the high-voltage LED chip, and would be prone to problems such as fracture, etc. The crack as shown in FIG. 1 will easily cause problems such as aging and burning of the high-voltage LED chip.

### SUMMARY OF THE PRESENT DISCLOSURE

The present application provides a manufacturing method for a high-voltage LED chip, so as to solve the problems of poor metal bridging coverage at an isolation groove of the current high-voltage LED chip, easy aging and burn-out of the high-voltage LED chip, etc.

A manufacturing method for a high-voltage LED chip comprises: acquiring a preset substrate, wherein the preset substrate comprises sapphire Al₂O₃;
forming a layer of silicon oxide (SiO₂) on a surface layer of the sapphire Al₂O₃; photoetching a sapphire substrate PSS, wherein the sapphire substrate PSS comprises an upper layer and a lower layer, the upper layer being the silicon oxide (SiO₂), and the lower layer being the sapphire Al₂O₃; bridging an isolation groove by an inductively coupled plasma process, and then etching through all epitaxies of the isolation groove so as to expose the sapphire substrate PSS; corroding the sapphire substrate PSS to remove the silicon oxide (SiO₂) on the upper layer so that the sapphire substrate PSS forms a platform structure; and generating a high-voltage LED chip based on the platform structure according to preset requirements.

Further, forming a layer of silicon oxide (SiO₂) on a surface layer of the sapphire Al₂O₃ comprises: forming a layer of silicon oxide (SiO₂) on the surface layer of the sapphire Al₂O₃ by a preset deposition mode, wherein the preset deposition mode comprises ion assisted deposition, sputter deposition, and plasma-enhanced chemical vapor deposition.

Further, corroding the sapphire substrate PSS to remove the silicon oxide (SiO₂) on the upper layer comprises: soaking the sapphire substrate PSS with a buffered oxide etchant (BOE), wherein the soaking time is in the range of 3 to 30 minutes; and after the soaking is completed, the silicon oxide (SiO₂) is removed by the buffered oxide etchant (BOE) so that the sapphire substrate PSS forms a platform structure.

Further, the manufacturing method for a high-voltage LED chip further comprises: depositing a layer of silicon oxide (SiO₂) or silicon nitride (SiNx) on a surface of the high-voltage LED chip by plasma-enhanced chemical vapor deposition, and patterning the deposited high-voltage LED chip by photoetching and wet etching.

Further, the manufacturing method for a high-voltage LED chip further comprises: depositing a layer of a transparent conductive layer on the surface of the high-voltage LED chip by sputter deposition or reactive plasma deposition (RPD) process, a thickness of the conductive layer being 10 to 300 nm; and removing excess portions of the transparent conductive layer by photoetching and wet etching, wherein the excess portion is determined by the high-voltage LED chip and user requirements.

Further, the manufacturing method for a high-voltage LED chip further comprises: etching an N-type gallium nitride on an epitaxial wafer of the high-voltage LED chip to expose the N-type gallium nitride.

Further, the manufacturing method for a high-voltage LED chip further comprises: fabricating a metal electrode by electron beam evaporation, wherein materials of the metal electrode comprise chromium (Cr), titanium (Ti), aluminum (Al), silver (Ag), nickel (Ni), platinum (Pt), and gold (Au), and the thickness of the metal electrode is in the range of 1 to 5 microns.

Further, the method for producing a high-voltage LED chip comprises cutting, spot measurement, automatic optical inspection (AOI) and sorting.

Further, the manufacturing method for a high-voltage LED chip further comprises: plating the surface of the high-voltage LED chip with a silicon oxide (SiO₂) or titanium dioxide (TiO₂) stack layer by plasma assisted deposition, so that the surface of the high-voltage LED chip forms a Bragg reflector to improve the brightness of the high-voltage LED chip.

Further, the manufacturing method for a high-voltage LED chip further comprises: grinding the high-voltage LED chip to thin the high-voltage LED chip to a target thickness.

It can be seen from the above-mentioned technical solution that the present application provides a manufacturing method for a high-voltage LED chip, comprising acquiring a preset substrate, wherein the preset substrate comprises sapphire Al₂O₃, forming a layer of silicon oxide (SiO₂) on the surface layer of the sapphire Al₂O₃; photoetching a sapphire substrate PSS, wherein the sapphire substrate PSS comprises an upper layer and a lower layer, the upper layer being silicon oxide (SiO₂), and the lower layer being sapphire Al₂O₃; bridging an isolation groove by an inductively coupled plasma process, and then etching through all epitaxies of the isolation groove so as to expose the sapphire substrate PSS; corroding the sapphire substrate PSS to remove the upper silicon oxide (SiO₂) on the upper layer so that the sapphire substrate PSS forms a platform structure; and generating the high-voltage LED chip based on the platform structure according to preset requirements. The sapphire substrate PSS in the embodiments of the present application has a double-layer structure with an upper layer and a lower layer, the upper layer is silicon oxide (SiO₂), and the lower layer is sapphire Al₂O₃. Before making the sapphire Al₂O₃ patterned, a layer of silicon oxide (SiO₂) is deposited on the sapphire Al₂O₃, and then the sapphire substrate PSS is made by dry etching, and the substrate is used to fabricate the high-voltage LED chip. After the isolation groove is etched and bridged by the inductively coupled plasma (ICP), the sapphire substrate PSS is corroded so that the silicon oxide (SiO₂) above the sapphire Al₂O₃ is removed. A flat platform is formed at the isolation groove of the high-voltage LED chip, which is convenient to subsequently cover the bridging metal, thereby solving the problems such as bridging metal fractures.

### BRIEF DESCRIPTION OF THE DRAWINGS

In order to illustrate the technical scheme of the present application more clearly, the following will briefly introduce the drawings needed in the embodiments. Obviously, for those of ordinary skills in the art, without involving creative efforts, other drawings can also be obtained from these drawings.

FIG. 1 is a schematic view showing a cross-sectional structure of a high-voltage LED chip product in an embodiment;

FIG. 2 is a schematic view showing the cross-section of an isolation groove of the high-voltage LED chip product of FIG. 1;

FIG. 3 is a schematic view of a cross-sectional structure of a high-voltage LED chip product according to an embodiment of the present application;

FIG. 4 is a schematic view of a double-layer structure of a sapphire substrate PSS pattern according to an embodiment of the present application;

FIG. 5 is a schematic view of etching out an N-type gallium nitride on an epitaxial wafer of a high-voltage LED chip according to an embodiment of the present application;

FIG. 6 is a schematic view of a cross-sectional structure after supplementary epitaxial growth according to an embodiment of the present application;

FIG. 7 is a schematic view showing a structure of exposing a sapphire substrate PSS pattern by etching all the epitaxies in an isolation groove according to an embodiment of the present application;

FIG. 8 is a schematic view of a sapphire substrate PSS forming a platform structure according to an embodiment of the present application.

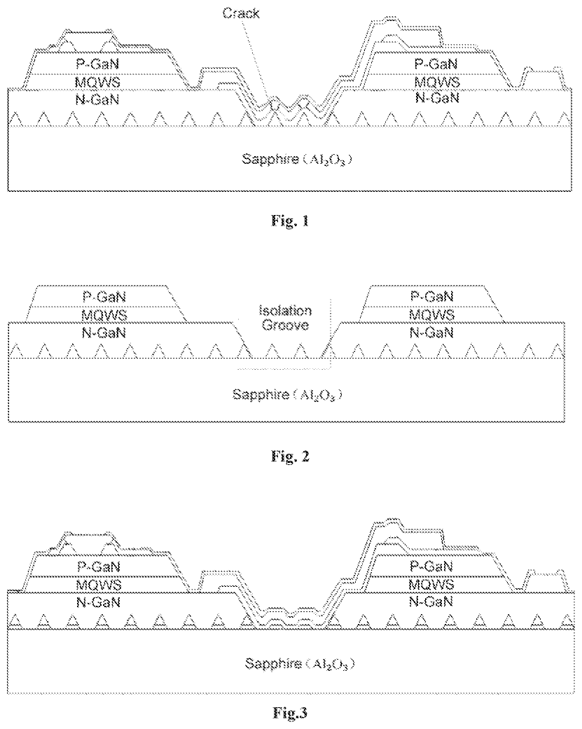

### DESCRIPTION OF THE EMBODIMENTS

In order to make the objects, technical solutions, and advantages of the present application clearer, the technical solutions of the present application will be clearly and completely described below in conjunction with the specific embodiments of the present application and the corresponding drawings. Obviously, the described embodiments are only some embodiments of the present application, rather than all embodiments. Based on the embodiments of the present application, all other embodiments obtained by a person of ordinary skills in the art without involving any inventive effort are within the scope of the present application. The technical solutions provided by the embodiments of the present application will be described in detail below with reference to the accompanying drawings.

In order to facilitate the understanding of the technical solutions of the embodiments of the present application, before explaining the preferred embodiments of the embodiments of the present application, some technical terms in the technical field to which the embodiments of the present application belong are firstly briefly explained.

GaN: which is gallium nitride, an inorganic substance, a compound of nitrogen and gallium, and commonly used in a light-emitting diode. Having a high hardness and a wide energy gap, the gallium nitride can be used in high power and high-speed photoelectric elements. For example, the gallium nitride can be used in purple laser diodes to generate purple light (405 nm) lasers without the use of nonlinear diode-pumped solid-state lasers.

P-GaN: which is a P-type gallium nitride obtained by doping with Mg. N-GaN is an N-type gallium nitride obtained by doping with Si. The active layer between the P-type gallium nitride and the N-type gallium nitride is a multiple-quantum-well (MQW). Generally, there will be multiple MQWs between the P-type gallium nitride and the N-type gallium nitride, so they are usually written as MQWS.

Sapphire: which is a blue precious stone, and in the embodiments of the present application, the underlying substrates of all figures are sapphire, also referred to as sapphire Al₂O₃.

PSS: which is an abbreviation for Patterned Sapphire Substrate, meaning a patterned sapphire substrate. Patterned Sapphire Substrate (PSS) is formed by growing a mask for dry etching on sapphire substrate, etching the mask to obtain a pattern by using a standard photolithographic process, etching the sapphire by using inductively coupled plasma (ICP) etching technique, and removing the mask. The GaN material is then grown on it to change the longitudinal epitaxy of the GaN material to a lateral epitaxy. On the one hand, the dislocation density of GaN epitaxial material can be effectively reduced so that the non-radiative recombination in the active region can be reduced, the reverse leakage current can be reduced, and the lifetime of the LED can be improved. On the other hand, the light emitted from the active region is scattered multiple times through GaN and the sapphire substrate interface, thereby changing the angle of emergence of the totally reflected light, increasing the probability of the flip LED light exiting from the sapphire substrate, and thus improving the light extraction efficiency. Combining these two reasons, the brightness of the emergent light of the LED grown on PSS is greatly improved compared to that of the traditional LED, and the reverse leakage current is reduced and the lifetime of the LED is extended.

Dry etching: which is a technique for etching thin films with plasma. When the gas exists in the form of plasma, it has two features. On the one hand, the chemical activity of these gases in the plasma is much stronger than that in the normal state, and according to the different materials to be etched, selecting a suitable gas can react with the material more quickly, so as to achieve the purpose of etching removal; on the other hand, the electric field can also be used to guide and accelerate the plasma, so that the plasma has a certain energy, and when striking the surface of the etched object, the plasma will knock out the atoms of the material to be etched, so as to achieve the purpose of etching by physical energy transfer.

LED face-up: a face-up structure, typically coated with a layer of epoxy on top, taking sapphire as the substrate on the bottom, and the electrode being on the top. The materials from top to bottom are a P-type gallium nitride, a light-emitting layer, an N-type gallium nitride, and a substrate. The light emitted from the active region of the face-up structure exits via the P-type gallium nitride region and a transparent electrode. The method used is to prepare a metal transparent electrode on the P-type gallium nitride so as to stably diffuse the current and achieve the purpose of uniform light emission.

LED flip: a flip chip technology, which use a gold wire bonding wire mechanism to make two golden wire ball welding spots under the P-pole and N-pole of the chip, use the same as the lead-out mechanism of the electrode, and use the gold wire to connect the outer side of the chip to the bottom board. The LED chip is flip-chip bonded to the silicon substrate by bumps. In this way, the heat generated by the high power LED does not have to pass through the sapphire substrate of the chip, but instead passes directly to the silicon or ceramic substrate with higher thermal conductivity and then to a metal base.

After a brief explanation of some technical terms in the technical field to which the embodiments of the present application belong, a manufacturing method for a high-voltage LED chip provided by the embodiments of the present application is described below.

At present, all the substrate processes of a high-voltage LED chip use sapphire Al₂O₃. Because of the material, process and procedures, etc. the patterned sapphire substrate PSS on sapphire Al₂O₃ cannot be planarized. Therefore, since the isolation groove of the high-voltage LED chip cannot be modified into a flat platform, problems such as poor metal bridging coverage, fractures, etc. at the isolation groove of the high-voltage LED chip are easily caused. Aiming to solve the current problems of poor metal bridging coverage at the isolation groove of the high-voltage LED chip, the high-voltage LED chip being easy to age and burn out, etc., the present application provides a manufacturing method for a high-voltage LED chip. In embodiments of the present application, a manufacturing method for a high-voltage LED chip may comprise the following contents:
acquiring a preset substrate, wherein the preset substrate comprises sapphire Al₂O₃; forming a layer of silicon oxide (SiO₂) on the surface layer of sapphire Al₂O₃; photoetching a sapphire substrate PSS, wherein the sapphire substrate PSS comprises an upper layer and a lower layer, the upper layer being silicon oxide (SiO₂), and the lower layer being sapphire Al₂O₃; bridging the isolation groove by an inductively coupled plasma process, and then etching through all the epitaxies of the isolation groove so as to expose the sapphire substrate PSS; corroding the sapphire substrate PSS to remove the silicon oxide (SiO₂) on the upper layer so that the sapphire substrate PSS forms a platform structure; and generating the high-voltage LED chip based on the platform structure according to the preset requirements.

The scenario applied by the embodiments of the present application is to provide a preset substrate in order to improve the metal bridging coverage at the isolation groove of the high-voltage LED chip and prevent the problems of aging, burn-out, etc. of the high-voltage LED chip. The preset substrate is a novel substrate, while the current substrate processes are all sapphire Al₂O₃, and therefore the preset substrate in the present application is different from the substrate of the art.

The sapphire substrate PSS in the embodiments of the present application has a double-layer structure with an upper layer and a lower layer, wherein the upper layer is silicon oxide (SiO₂), and the lower layer is sapphire Al₂O₃. Before patterning the sapphire Al₂O₃, a layer of silicon oxide (SiO₂) is deposited on the sapphire Al₂O₃, e.g., a case where the deposited layer of silicon oxide (SiO₂) may be 100 to 5000 Angstroms. The sapphire substrate PSS is then formed by dry etching and the structure is divided into an upper layer and a lower layer as described above. The high-voltage LED chip is formed by using the substrate. After the isolation groove is etched and bridged by the inductively coupled plasma (ICP), the sapphire substrate PSS is corroded, and the silicon oxide (SiO₂) above the sapphire Al₂O₃ is removed. Compared with current technology where all the substrate processes of the high-voltage LED chip use sapphire Al₂O₃, while in an embodiment of the present application, there is silicon oxide (SiO₂) above the sapphire Al₂O₃ in the preset substrate. In this way, a flat platform is formed at the isolation groove of the high-voltage LED chip, which is convenient to subsequently cover the bridging metal, thereby solving the problems such as bridging metal fractures.

FIG. 3 is a schematic view of a cross-sectional structure of a high-voltage LED chip product according to an embodiment of the present application. In the specific implementation process, the preset substrate in the embodiments of the present application is subjected to GaN deposition, and N-type gallium nitride (N-GaN), multi-quantum well (MQWS), and P-type gallium nitride (P-GaN) are sequentially deposited.

In some embodiments, the manufacturing method for sapphire substrate PSS may comprise forming a layer of silicon oxide (SiO₂) on the surface layer of the sapphire Al₂O₃. Specifically, the surface layer of the sapphire Al₂O₃ forms a layer of silicon oxide (SiO₂) via preset deposition mode, for example, a layer of silicon oxide (SiO₂) of 100 to 10000 angstroms may be formed. The preset deposition mode may include ion assisted deposition, sputter deposition, plasma-enhanced chemical vapor deposition (PECVD), etc. Among them, the plasma-enhanced chemical vapor deposition is generally used for the production of artificial diamonds, and this method has many advantages, such as high color grade, good film-forming quality, etc.

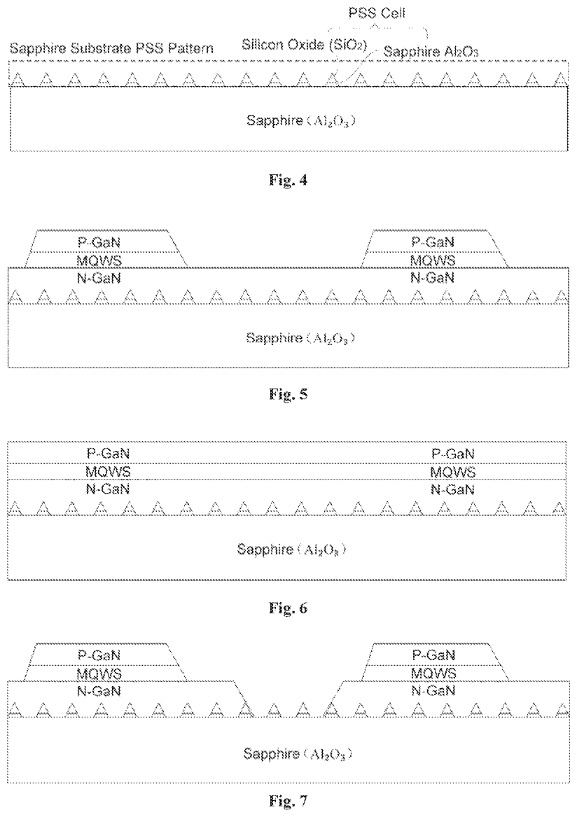

After a layer of silicon oxide (SiO₂) is formed on the surface layer of the sapphire Al₂O₃, a sapphire substrate PSS pattern can be made by photoetching, and etching is performed by using an inductively coupled plasma (ICP) to form a PSS cell with an upper layer of silicon oxide (SiO₂) and a lower layer of sapphire Al₂O₃, as shown in FIG. 4.

In some embodiments, an N-type gallium nitride (N-GaN) is etched on a high-voltage LED chip epitaxial wafer by using the inductively coupled plasma (ICP) process to expose the N-type gallium nitride, as shown in FIG. 5. In this way, the exposed N-type gallium nitride can be left for use during forming a metal negative electrode, as well as for cutting path and to be used when determining the size of the chip and determining the number of series and parallel connection.

In some other embodiments, reference is made to FIG. 6. FIG. 6 is a schematic view of a cross-sectional structure after supplementary epitaxial growth according to an embodiment of the present application, the supplementary structure being shown in FIG. 6 after the epitaxy is supplemented.

In order to make a sapphire substrate PSS pattern, in one implementation mode, as shown in FIG. 7, through photoetching and inductively coupled plasma (ICP) process, all the epitaxies in the isolation groove are etched through, exposing the sapphire substrate PSS pattern, wherein photoetching is a major process in the production of planar transistors and integrated circuits, in which a hole is made in the mask on the surface of a semiconductor wafer for the fixed-domain diffusion of impurities.

In order to remove the silicon oxide (SiO₂) of the upper layer of the sapphire substrate PSS, one implementation mode may be to corrode the sapphire substrate PSS to remove the silicon oxide (SiO₂) of the upper layer. The following steps can be included: soaking the sapphire substrate PSS with a buffered oxide etchant (BOE), the soaking time being in the range of 3 to 30 minutes, wherein corroding with the buffered oxide etchant (BOE) needs to soak the corroded material in the corroding process, and therefore, the process can be referred to as a wet BOE etching; after the soaking is completed, the silicon oxide (SiO₂) is removed by soaking with the buffered oxide etchant (BOE) so that the sapphire substrate PSS forms a platform structure.

The buffered oxide etchant (BOE) is prepared by mixing hydrofluoric acid HF (49%) with water or with ammonium fluoride (NH₄F) and water. The hydrofluoric acid (HF) is the main etchant and the ammonium fluoride (NH₄F) is used as a buffering agent. The buffered oxide etchant (BOE) has a certain etching rate, for example, the hydrofluoric acid (HF) may erode glass and any silica-containing substance.

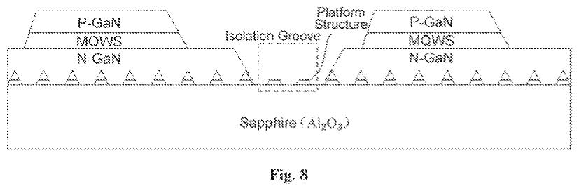

For example, the silicon oxide (SiO₂) on the surface of the sapphire substrate PSS can be removed, by soaking the sapphire substrate PSS with the buffered oxide etchant (BOE) for 3 to 30 minutes and by the corrosive effect of the buffered oxide etchant (BOE), to form a complete platform structure, as shown in FIG. 8. That is to say, in the embodiment of the present application, based on a double-layer preset substrate, a flat platform is fabricated at an isolation groove of a high-voltage LED chip in combination with a wet BOE etching after an inductively coupled plasma (ICP) etching process is performed on a sapphire substrate PSS. In this way, after the isolation groove is etched by ICP, wet BOE etching is performed to remove the silicon oxide SiO₂ on the upper layer, and a platform structure as shown in FIG. 8 is formed at the isolation groove. The platform-type structure can make the metal coverage better, so as to solve the problem of poor metal bridging coverage at the isolation groove of the current high-voltage LED chip.

In order to draw high-voltage LED chips of various shapes, in one implementation mode, a layer of silicon oxide (SiO₂) or silicon nitride (SiNx) is deposited on the surface of the high-voltage LED chip by plasma-enhanced chemical vapor deposition, and the deposited high-voltage LED chip is patterned by photoetching and wet etching.

For example, silicon oxide (SiO₂) or silicon nitride SiNx of 50 to 500 nm can be deposited on the surface of a high-voltage LED chip by the process of plasma-enhanced chemical vapor deposition (PECVD), and the required pattern can be made by photoetching and wet etching so that a variety of high-pressure LED chip shapes can be drawn according to the above steps. Meanwhile, silicon oxide (SiO₂) or silicon nitride (SiNx) is deposited by plasma-enhanced chemical vapor deposition (PECVD) (the deposition thickness may be 500-10000 angstroms, for example), the required pattern is etched by photoetching, and the excess silicon oxide (SiO₂) or silicon nitride (SiNx) is removed by wet etching or ICP to expose the P/N electrode.

In another implementation method, a layer of a transparent conductive layer can be deposited on the surface of the high-voltage LED chip by a sputter deposition or a reaction plasma deposition (RPD) process, and the thickness of the conductive layer is 10 to 300 nm. The excess portion of the transparent conductive layer is removed by photoetching and wet etching, wherein the excess portion is determined by the high-voltage LED chip and user requirements.

For example, a layer of transparent conductive layer indium tin oxide (ITO) is deposited on the surface of the high-voltage LED chip through the sputter deposition or the reactive plasma deposition (RPD) process, wherein the indium tin oxide (ITO) is a transparent layer and a mixture, being a transparent tan thin-film or a yellowish-grey block shape, and is mainly used for ohmic contact and current conduction diffusion of a P-type gallium nitride, and can also be used for a liquid crystal display, a flat panel display, a plasma display, a touch screen, electronic paper, an organic light-emitting diode, a solar cell, an antistatic film coating, an EMI shielding transparent conductive coating, various optical film coatings, etc. In the embodiment of the present application, the thickness of the indium tin oxide (ITO) can be in the range of 10 to 300 nm, and the excess portion of indium tin oxide (ITO) can be removed by photoetching and wet etching, thereby designing the required pattern according to the high-voltage LED chip product.

In some embodiments, using electron beam evaporation to fabricate a metal electrode is also included. The materials of the metal electrode comprise chromium (Cr), titanium (Ti), aluminum (AI), silver (Ag), nickel (Ni), platinum (Pt), and gold (Au), and the thickness of the metal electrode is in the range of 1 to 5 microns. For example, the required pattern of the metal electrode can be etched by photoetching.

During the actual operation, the required high-voltage LED chip can be produced by a series of methods, such as cutting, spot measurement, automatic optical inspection (AOI) and sorting. In order to improve the reflectivity of the preset substrate and the brightness of the high-voltage LED chip, one implementation mode may comprise plating the surface of the high-voltage LED chip with a silicon oxide (SiO₂) or titanium dioxide (TiO₂) stack layer by plasma assisted deposition, whereby the surface of the high-voltage LED chip forms a Bragg reflector to improve the brightness of the high-voltage LED chip.

Specifically, the surface of the high-voltage LED chip can be coated with a silicon oxide (SiO₂) or a titanium dioxide (TiO₂) stack layer by plasma assisted deposition, whereby the high-voltage LED chip is formed as a Bragg reflector so as to improve the brightness of the high-voltage LED chip. The titanium dioxide (TiO₂) is an inorganic material, being white solid or powdery amphoteric oxide with non-toxicity, optimal opacity, optimal whiteness, and light brightness, which is considered to be the best white pigment in the world today. That is to say, the preset substrate (a double-layer novel structure) in the embodiments of the present application can improve the substrate reflectivity of the high-voltage LED chip and the brightness of the high-voltage LED chip, thereby solving the problems of easy aging, burn-out, etc. of the high-voltage LED chip.

During the actual operation, it is also necessary to grind the high-voltage LED chip to thin the high-voltage LED chip to a target thickness. It should be noted that although the above-mentioned method and steps are a manufacturing process of face-up high-voltage LED chip, and the embodiments of the present application also protect a high-voltage LED chip manufacturing process related to flip-chip, etc. The inventive points of the present application are also suitable for a high-voltage LED chip manufacturing process related to flip-chip, etc.

It can be seen from the above-mentioned technical solution that the present application provides a manufacturing method for a high-voltage LED chip, comprising: acquiring a preset substrate, wherein the preset substrate comprises sapphire Al₂O₃; forming a layer of silicon oxide (SiO₂) on the surface layer of the sapphire Al₂O₃; photoetching a sapphire substrate PSS, wherein the sapphire substrate PSS comprises an upper layer and a lower layer, the upper layer being silicon oxide (SiO₂), and the lower layer being sapphire Al₂O₃; bridging an isolation groove by an inductively coupled plasma process, and then etching through all epitaxies of the isolation groove so as to expose the sapphire substrate PSS; corroding the sapphire substrate PSS to remove the upper silicon oxide (SiO₂) on the upper layer so that the sapphire substrate PSS forms a platform structure; and generating the high-voltage LED chip based on the platform structure according to preset requirements. The sapphire substrate PSS in the embodiments of the present application has a double-layer structure with an upper layer and a lower layer, the upper layer is silicon oxide (SiO₂), and the lower layer is sapphire Al₂O₃. Before making the sapphire Al₂O₃ patterned, a layer of silicon oxide (SiO₂) is deposited on the sapphire Al₂O₃, and then the sapphire substrate PSS is made by dry etching, and the substrate is used to fabricate the high-voltage LED chip. After etching and bridging the isolation groove by the inductively coupled plasma (ICP), the sapphire substrate PSS is corroded. The silicon oxide (SiO₂) above the sapphire Al₂O₃ is removed. A flat platform is formed at the isolation groove of the high-voltage LED chip, which is convenient to subsequently cover the bridging metal, thereby solving the problems such as bridging metal fractures.

Other implementation schemes of the present invention will be apparent to those skilled in the art from the consideration of the description and the practice of the invention disclosed herein. This application is intended to cover any variations, uses, or adaptations of the invention that follow the general principles of the invention and include common knowledge or conventional techniques in the art not disclosed by the invention.

It should be understood that the invention is not limited to the precise structures described above and shown in the accompanying drawings, and that various modifications and changes may be made without departing from the scope of the present invention. The scope of the invention is only limited by the appended claims.

What is claimed is:

1. A manufacturing method for a high-voltage LED chip, comprising:
acquiring a preset substrate, wherein the preset substrate comprises sapphire Al₂O₃;
forming a layer of silicon oxide (SiO₂) on a surface layer of the sapphire Al₂O₃;
photoetching a sapphire substrate PSS, wherein the sapphire substrate PSS comprises an upper layer and a lower layer, the upper layer being the silicon oxide (SiO₂), and the lower layer being the sapphire Al₂O₃;
bridging an isolation groove by an inductively coupled plasma process, and then etching through all epitaxies of the isolation groove so as to expose the sapphire substrate PSS;
corroding the sapphire substrate PSS to remove the silicon oxide (SiO₂) on the upper layer so that the sapphire substrate PSS forms a platform structure; and
generating a high-voltage LED chip based on the platform structure according to preset requirements.

2. The manufacturing method for a high-voltage LED chip according to claim 1, wherein forming the layer of silicon oxide (SiO₂) on the surface layer of the sapphire Al₂O₃ comprises:
forming the layer of silicon oxide (SiO₂) on the surface layer of the sapphire Al₂O₃ by a preset deposition mode;
wherein the preset deposition mode comprises ion assisted deposition, sputter deposition, and plasma-enhanced chemical vapor deposition.

3. The manufacturing method for a high-voltage LED chip according to claim 1, wherein corroding the sapphire substrate PSS to remove the silicon oxide (SiO₂) on the upper layer comprises:
soaking the sapphire substrate PSS with a buffered oxide etchant (BOE), wherein the soaking time is in the range of 3 to 30 minutes; and
after the soaking is completed, the silicon oxide (SiO₂) is removed by the buffered oxide etchant (BOE) so that the sapphire substrate PSS forms a platform structure.

4. The manufacturing method for a high-voltage LED chip according to claim 1, further comprising:
depositing a layer of silicon oxide (SiO₂) or silicon nitride (SiNx) on a surface of the high-voltage LED chip by plasma-enhanced chemical vapor deposition, and patterning deposited high-voltage LED chip by photoetching and wet etching.

5. The manufacturing method for a high-voltage LED chip according to claim 1, further comprising:
depositing a layer of a transparent conductive layer on the surface of the high-voltage LED chip by sputter deposition or reactive plasma deposition (RPD) process, a thickness of the conductive layer being 10 to 300 nm; and
removing excess portions of the transparent conductive layer by photoetching and wet etching, wherein the excess portion is determined by the high-voltage LED chip and user requirements.

6. The manufacturing method for a high-voltage LED chip according to claim 1, further comprising: etching an N-type gallium nitride on an epitaxial wafer of the high-voltage LED chip to expose the N-type gallium nitride.

7. The manufacturing method for a high-voltage LED chip according to claim 1, further comprising: fabricating a metal electrode by electron beam evaporation, wherein materials of the metal electrode comprise chromium (Cr), titanium (Ti), aluminum (Al), silver (Ag), nickel (Ni), platinum (Pt), and gold (Au), and the thickness of the metal electrode is in the range of 1 to 5 microns.

8. The manufacturing method for a high-voltage LED chip according to claim 1, comprising cutting, spot measurement, automatic optical inspection (AOI) and sorting.

9. The manufacturing method for a high-voltage LED chip according to claim 1, further comprising: plating the surface of the high-voltage LED chip with a silicon oxide (SiO₂) or titanium dioxide (TiO₂) stack layer by plasma assisted deposition, so that the surface of the high-voltage LED chip forms a Bragg reflector to improve brightness of the high-voltage LED chip.

10. The manufacturing method for a high-voltage LED chip according to claim 1, further comprising: grinding the high-voltage LED chip to thin the high-voltage LED chip to a target thickness.
